(19) United States
(12) Patent Application Publication
(10) Pub. No.: US 2012/0297796 A1
(43) Pub. Date: Nov. 29, 2012

(54) THIN FILM PELTIER THERMAL LIGHT POWER BARRIER COOLER

(76) Inventor: Joseph R. Schwarz, Alta Loma, CA (US)

(21) Appl. No.: 13/117,688

(22) Filed: May 27, 2011

(51) Int. Cl. F25B 21/02; H01L 21/02

(52) U.S. Cl. 62/3.7; 438/54; 257/E21.002

(57) ABSTRACT

A light powered barrier for cooling a substrate includes a thermo-conductive layer for contacting the substrate, a first P-type layer disposed atop the thermo-conductive layer, a first N-type layer disposed over the first P-type layer and a thermoelectrically conductive insert that conducts heat from the thermo-conductive layer and electrically conducts electrons and holes from the first P-type layer and the first N-type layer.

### BACKGROUND

Thin film light cells, which are also called thin film photovoltaic cells, are light cells that are made by depositing one or more thin layers of a P-type material upon one or more layers of an N-type material. An electric current is created when light hits the materials as electrons and/or electron holes flow from the N-type material to P-type material. This flow may be tapped and used for various applications.

Peltier thermal electric devices are made from alternating P-type and N-type materials that are connected by metallic interconnects and have a power supply. The power supply provides a current that flows through the junctions of the materials to provide cooling or a cooling effect. Electrons in the N-type material move opposite the direction of current and holes in the P-type material move in the direction of current, both moving heat from one side of the device to the other.

### SUMMARY

According to an embodiment disclosed herein, a light powered barrier for cooling a substrate includes a thermo-conductive layer for contacting the substrate, a first P-type layer disposed atop the thermo-conductive layer, a first N-type layer disposed over the first P-type layer and a thermoelectrically conductive insert that conducts heat from the thermo-conductive layer and electrically conducts electrons and holes from the first P-type layer and the first N-type layer.

According to a further embodiment disclosed herein, a method for cooling a substrate includes the steps of: providing a thermo-conductive layer for contacting a substrate to be cooled, providing a first P-type layer disposed atop the thermo-conductive layer, providing a first N-type layer disposed over the first P-type layer, providing a thermoelectrically conductive insert that conducts heat from the thermo-conductive layer and electrically conducts electrons and holes between the first P-type layer and the N-type layer and exposing the N-type layer to light to induce the conduction of electrons and holes from the thermo-conductive layer, the first P-type layer and the N-type layer to draw heat away from the substrate through the insert to ambient.

According to a still further embodiment disclosed herein, a method for constructing a light powered barrier for cooling a substrate includes the steps of providing a thermo-conductive layer for contacting a substrate, laying a first P-type layer atop the thermo-conductive layer, laying a first N-type layer atop the first P-type layer, and placing a thermoelectrically conductive insert in close proximity to the thermo-conductive layer, the first P-type layer and the first N-type layer such that the insert conducts heat from the thermo-conductive layer and electrically conducts electrons and holes from the first P-type layer and the N-type layer.

### BRIEF DESCRIPTION OF THE DRAWINGS

The various features and advantages of the disclosed examples will become apparent to those skilled in the art from the following detailed description. The drawings that accompany the detailed description can be briefly described as follows.

FIG. 1 shows an embodiment of a thin film Peltier thermal light powered barrier cooler.

FIG. 2 shows a method of constructing the bather cooler of FIG. 1.

### DETAILED DESCRIPTION OF THE PREFERRED EMBODIMENT

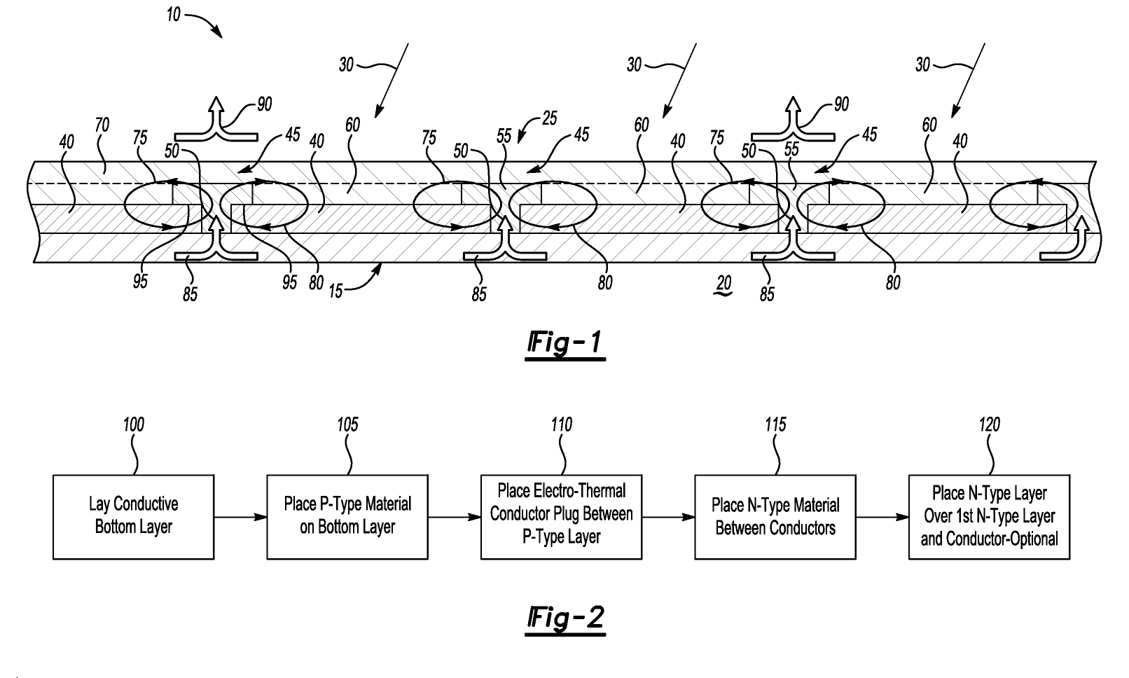

Referring now to FIG. 1, a thin film peltier thermal light powered barrier cooler 10 is shown. Such coolers 10 may be used in any application in which the back side or bottom layer 15 of the cooler 10 is desired to be cooler to cool objects 20 such as, but not limited, to space suits, roofing panels, food chillers, medicine holders, etc.

Describing the material from the bottom layer 15 which is designed to be placed on an object 20 to be cooled to the top layer 25 of the cooler 10, which is exposed to the light 30. The bottom layer 15 may be aluminum or other thermo-conductive material. The bottom layer 15 may include a mesh overlay 35 for promoting cooling air therethrough and is covered with a plurality of spaced P-type material layers 40, which may be silicon doped with boron, aluminum, or gallium. The P-type material layers 40 are separated by electro/thermal conductive t-shaped spacers 45. Each T-shaped insert or spacer 45 has a vertical portion 50 and a cross portion 55 disposed atop of the vertical portion 50. The T-shaped spacer 45 may have other shapes.

An N-type material first layer 60, such as silicon doped with phosphorus or arsenic or a cadmium disulfide or the like, is disposed in between the cross portions 55 and on top of and contacting the P-type material layer 40, and a second layer 70 of an N-type material overlays the first layer 60 of N-type material and the cross portion 55 of the t-shaped spacer 45.

If light strikes the cooler 10, holes (not shown) flow in a direction of current indicated by arrows 75 and 80 and electrons (not shown) flow in an opposite direction of the arrows 75 and 80 such that heat indicated by arrows 85 is induced to flow from the bottom layer 15 through the vertical portion 50 to the cross portion 55 and therefrom through the second layer 70 of N-type material to ambient as shown by arrows 90 thereby cooling bottom layer 15 and object 20.

By combining a thin film light type power device with a Peltier-effect device, a light-powered cooler 10 is created that has very little cost to run. In a more typical arrangement, the bottom layer of aluminum in a cooling application requires a heat sink and fins (not shown). In this application, fins and sinks (not shown) may be minimized if not eliminated.

Referring to FIG. 2, the process of creating the thin film peltier thermal light power barrier cooler 10 is described. The bottom layer 15 of thermo-conductive material is provided (step 100). A P-type material layer 40 is silk screened onto the bottom layer 15 (step 105). T-shaped spacers 45 may be placed between the layers P-type material layers 40 such that the cross portion 55 of each spacer 45 is in contact with a top 95 of two of the adjacent P-type material layers 40 and the vertical portion 50 is in contact with the cross portion 55, the bottom layer 15 and each adjacent P-type material layer 40 (step 110). The first layer 60 of N-type material is silk screened between the cross portions 55 of the t-shaped spacers 45 (step 115). After placing the N-type material between the cross portions 55, the N-type material second layer 70 is disposed atop the first layer 60 of N-type material and the cross portions 55 to build to the desired level (step 120). As an alternative, steps 115 and 120 may be combined to deposit the first and second layers 60, 70 as one thicker layer. Other methods of laying N-type material and P-type material upon the bottom layer 15 such as photographic and chemical processing (not shown) or the like are contemplated herein.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from the essence of this disclosure. The scope of legal protection given to this disclosure can only be determined by studying the following claims.

What is claimed is:

1. A light powered barrier for cooling a substrate comprising:
a thermo-conductive layer for contacting said substrate;
a first P-type layer disposed atop said thermo-conductive layer;
a first N-type layer disposed over said first P-type layer; and
a thermoelectrically conductive insert that conducts heat from said thermo-conductive layer and electrically conducts electrons and holes from said first P-type layer and said first N-type layer.

2. The barrier of claim 1 wherein said insert has a portion atop said first P-type layer.

3. The barrier of claim 1 further comprising a second N-type layer disposed atop said first N-type layer.

4. The barrier of claim 1 wherein said thermo-conductive layer further comprises a mesh layer disposed in contact with said P-type layer.

5. The barrier of claim 1 wherein said thermo-conductive layer further comprises a mesh layer disposed in contact with said insert.

6. The barrier of claim 1 further comprising a second P-type layer disposed atop said thermo-conductive layer in close proximity to said first P-type layer.

7. The barrier of claim 6 wherein said insert comprises a vertical portion contacting said first and second P-type layers and a cross portion contacting a top of said first and second P-type layers.

8. A method for cooling a substrate comprising:
providing a thermo-conductive layer for contacting a substrate to be cooled;
providing a first P-type layer disposed atop said thermo-conductive layer;
providing an N-type layer disposed over said first P-type layer;
providing a thermoelectrically conductive insert that conducts heat from said thermo-conductive layer and electrically conducts electrons and holes between said first P-type layer and said N-type layer; and
exposing said N-type layer to light to induce the conduction of electrons and holes from said thermo-conductive layer, said first P-type layer and said N-type layer to draw heat away from said substrate through said insert to ambient.

9. The method of claim 8 further comprising placing a cross portion of said insert atop said first P-type layer.

10. The method of claim 8 wherein said N-type layer is comprised of a second N-type layer placed atop a first N-type layer.

11. The method of claim 8 wherein providing said thermo-conductive layer further comprises placing a mesh layer in contact with said first P-type layer and said thermo-conductive layer and said insert.

12. The method of claim 8 further comprising placing a second P-type layer atop said thermo-conductive layer in close proximity to said first P-type layer.

13. The method of claim 12 further comprising:
contacting a vertical portion of said insert with said first and second P-type layers and placing a cross portion of said insert in contact with a top of said first and second P-type layers.

14. A method for constructing a light powered bather for cooling a substrate comprising:
providing a thermo-conductive layer for contacting a substrate;
laying a first P-type layer atop said thermo-conductive layer;
laying a first N-type layer atop said first P-type layer; and
placing a thermoelectrically conductive insert in close proximity to said thermo-conductive layer, said first P-type layer and said first N-type layer such that said insert conducts heat from said thermo-conductive layer and electrically conducts electrons and holes from said first P-type layer and said first N-type layer.

15. The method of claim 14 further comprising placing a cross portion of said insert atop said first P-type layer.

16. The method of claim 14 further comprising placing a second N-type layer atop said first N-type layer.

17. The method of claim 14 further comprises placing said first N-type layer over said first P-type layer and said insert.

18. The method of claim 14 further comprising placing a second P-type layer atop said thermo-conductive layer in close proximity to said first P-type layer.

19. The method of claim 18 further comprising:
contacting a vertical portion of said insert with said first and second P-type layers; and
placing a cross portion of said insert in contact with a top of said first and second P-type layers.

20. The method of claim 18 further comprising placing a second N-type layer atop said first and second P-type layers and said insert.
